(19) United States
(12) Patent Application Publication
(10) Pub. No.: US 2026/0215351 A1
(43) Pub. Date: Jul. 23, 2026

(54) METHOD OF BONDING WAFER AND CHIP

(71) Applicant: SAMSUNG ELECTRONICS CO., LTD., Suwon-si (KR)

(72) Inventor: Dongsik SHIM, Suwon-si (KR)

(73) Assignee: SAMSUNG ELECTRONICS CO., LTD., Suwon-si (KR)

(21) Appl. No.: 19/246,037

(22) Filed: Jun. 23, 2025

(30) Foreign Application Priority Data
Jan. 14, 2025 (KR) 10-2025-0005600

(51) Int. Cl. H01L 23/00; H01L 25/065

(52) U.S. Cl. CPC H10W 99/00; H10W 72/0198; H10W 72/90; H10W 80/102; H10W 80/165; H10W 80/312; H10W 80/327; H10W 80/334; H10W 90/00; H10W 90/792

(57) ABSTRACT

A method may include: pre-bonding, by a liquid, a wafer to a chip, while the chip is attached to a jig; and detaching the jig after the pre-bonding, wherein the pre-bonding includes evaporating the liquid in a vacuum.

### CROSS-REFERENCE TO RELATED APPLICATION

This application is based on and claims priority under 35 U.S.C. § 119 to Korean Patent Application No. 10-2025-0005600, filed on Jan. 14, 2025, in the Korean Intellectual Property Office, the disclosure of which is incorporated by reference herein in its entirety.

### BACKGROUND

### 1. Field

Some embodiments of the present disclosure relate to a method of bonding a wafer and a chip.

### 2. Description of Related Art

A photonic integrated circuit (PIC) may be manufactured by patterning silicon. Devices used as light sources for PICs include lasers placed outside the PICs or laser diodes placed on the PICs. Among them, the laser diode provided on the PIC may be manufactured by attaching a group III-V wafer on a silicon wafer and then patterning the resultant.

In this case, in the PIC, a portion that requires group III-V materials is not more than several percent of the total area of the PIC. Accordingly, when wafer-to-wafer bonding is used, there is an issue that the waste of group III-V materials is severe.

### SUMMARY

According to some embodiments of the present disclosure, a method of bonding a wafer and a chip may be provided.

According to some embodiments of the present disclosure, a method may include: pre-bonding, by a liquid, a wafer to a chip, while the chip is attached to a jig; and detaching the jig after the pre-bonding, wherein the pre-bonding includes evaporating the liquid in a vacuum.

According to some embodiments of the present disclosure, wherein the chip may include a group III-V semiconductor.

According to some embodiments of the present disclosure, the liquid may include oxygen (O).

According to some embodiments of the present disclosure, the liquid may include water.

According to some embodiments of the present disclosure, the wafer may include a device.

According to some embodiments of the present disclosure, the device may include an optical waveguide or an antenna.

According to some embodiments of the present disclosure, the method may further include manufacturing a laser diode by processing the chip.

According to some embodiments of the present disclosure, the pre-bonding may include pre-bonding, via a surface tension of the liquid, the wafer to the chip.

According to some embodiments of the present disclosure, a method may include: pre-bonding, by a liquid, a wafer and a chip, while the chip is attached to a jig; detaching the jig; and post-bonding, by heat and pressure, the wafer to the chip after the pre-bonding, wherein the pre-bonding includes evaporating the liquid in a vacuum.

According to some embodiments of the present disclosure, the post-bonding may include subjecting the wafer and the chip to a pressure in a range of 0.5 atm to 4 atm.

According to some embodiments of the present disclosure, the post-bonding may include subjecting the wafer and the chip to a temperature in a range of 200° C. to 400° C.

According to some embodiments of the present disclosure, the post-bonding may include changing a bonding of the wafer and the chip, caused by the pre-bonding, into a covalent bonding.

According to some embodiments of the present disclosure, the chip may include a group III-V semiconductor.

According to some embodiments of the present disclosure, the liquid may include oxygen (O).

According to some embodiments of the present disclosure, the wafer may include a device.

According to some embodiments of the present disclosure, the device may include an optical waveguide or an antenna.

According to some embodiments of the present disclosure, the method may further include manufacturing a laser diode by processing the chip.

According to some embodiments of the present disclosure, the pre-bonding may include pre-bonding, via a surface tension of the liquid, the wafer to the chip.

According to some embodiments of the present disclosure, a method may include: pre-bonding, by a surface tension of a liquid, a wafer and a chip while the chip is attached to a jig, wherein the chip includes an optical waveguide or an antenna; detaching the jig; and post-bonding, by heat and pressure, the wafer to the chip after the pre-bonding, wherein the pre-bonding includes evaporating the liquid in a vacuum.

According to some embodiments of the present disclosure, the post-bonding may include subjecting the wafer and the chip to a pressure in a range of 0.5 atm to 4 atm and a temperature in a range of 200° C. to 400° C.

Additional aspects of the present disclosure will be set forth in part in the description which follows and, in part, will be apparent from the description, or may be learned by practice of the presented example embodiments of the present disclosure.

### BRIEF DESCRIPTION OF DRAWINGS

The above and other aspects, features and advantages of certain embodiments of the present disclosure will be more apparent from the following description taken in conjunction with the accompanying drawings, in which:

FIG. 1 is a cross-sectional view illustrating a bonded assembly of a wafer and a chip according to an embodiment;

FIG. 2 is a flowchart illustrating a method of bonding a wafer and a chip according to an embodiment;

FIG. 3 is a flowchart illustrating a method of bonding a wafer and a chip according to an embodiment; and

FIGS. 4 to 8 are cross-sectional views illustrating a method of bonding a wafer and a chip according to an embodiment.

### DETAILED DESCRIPTION

Reference will now be made in detail to non-limiting example embodiments of the present disclosure, examples of which are illustrated in the accompanying drawings, wherein like reference numerals refer to like elements throughout. In this regard, the embodiments of the present disclosure may have different forms and should not be construed as being limited to the descriptions set forth herein. Accordingly, example embodiments are described below, by referring to the figures, to explain non-limiting example aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a method of bonding a wafer and a chip according to various embodiments will be described in detail with reference to the accompanying drawings. In the drawings, the same reference numerals refer to the same components and the size of each component in the drawings may be exaggerated for clarity and convenience of description. In addition, the embodiments described below are merely examples, various modifications are possible from these embodiments, and the various modifications are included within the spirit and scope of the present disclosure.

Hereinafter, the term “upper portion” or “on” may also include “to be present above on a non-contact basis” as well as “to be on the top portion in direct contact with.” The singular expression includes plural expressions unless the context clearly implies otherwise. In addition, when a part “includes” (or “comprises”) a component, this means that the part may further include other components, not excluding other components unless otherwise stated.

The use of the term “the” and similar indicative terms may correspond to both singular and plural. If there is no explicit description or contrary description of the order of the steps or operations constituting the method, these steps or operations may be carried out in any appropriate order and are not necessarily limited to the described order.

The connection or connection members of lines between the components shown in the drawings exemplarily represent functional connection and/or physical or circuit connections and may be replaceable or represented as various additional functional connections, physical connections, or circuit connections in an actual device.

The use of all examples or terms is merely for describing example aspects of the present disclosure in detail, and the scope of the present disclosure is not limited to the examples or terms.

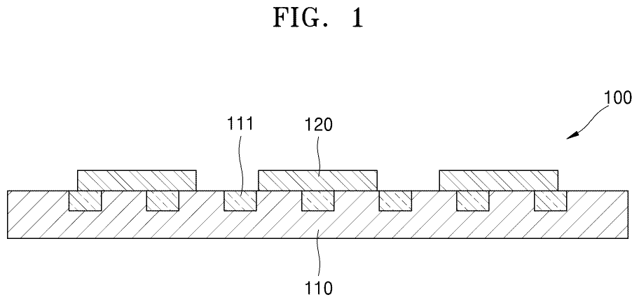

FIG. 1 is a cross-sectional view illustrating a bonded assembly of a wafer and a chip according to an embodiment.

Referring to FIG. 1, a bonded assembly 100 may include a wafer 110, at least one device 111, and the at least one chip 120.

The wafer 110 may include, for example, silicon. However, the material of the wafer 110 is not limited to silicon, and various wafer materials used in semiconductor manufacturing processes may be used.

The at least one device 111 may include a semiconductor material. The at least one device 111 may include, for example, silicon. The at least one device 111 may include, for example, an optical waveguide or an antenna.

The at least one chip 120 may include, for example, a group III-V semiconductor. The at least one chip 120 may include, for example, a compound semiconductor such as gallium arsenide (GaAs), indium arsenide (InAs), indium phosphide (InP), and the like. The at least one chip 120 may include a group III-V semiconductor and may be used to fabricate a laser diode or a semiconductor optical amplifier.

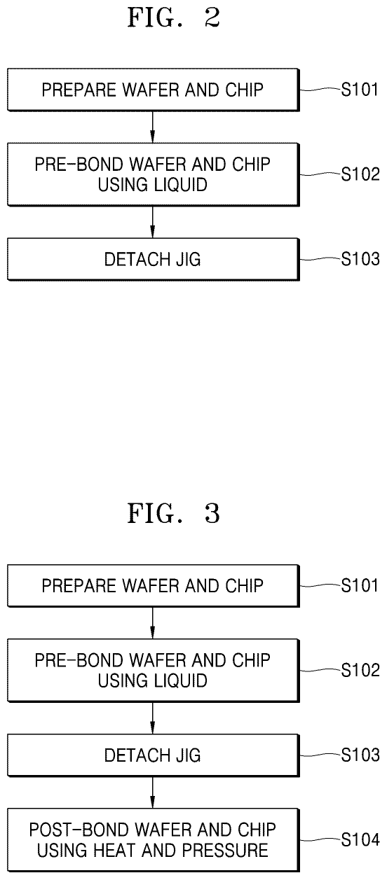

After the wafer 110 and the at least one chip 120 are bonded, the at least one chip 120 may be processed to manufacture a laser diode or a semiconductor optical amplifier. For example, according to an embodiment of the present disclosure, a method may be provided and include manufacturing a laser diode or a semiconductor optical amplifier by processing the at least one chip, after bonding the wafer 110 and the at least one chip 120 as, for example, described below with reference to FIGS. 2-8.

FIG. 2 is a flowchart illustrating a method of bonding a wafer and a chip according to an embodiment.

Referring to FIG. 2, a method of bonding a wafer and a chip may include an operation S101 of preparing a wafer and a chip, an operation S102 of pre-bonding the wafer and the chip using a liquid, and an operation S103 of detaching a jig.

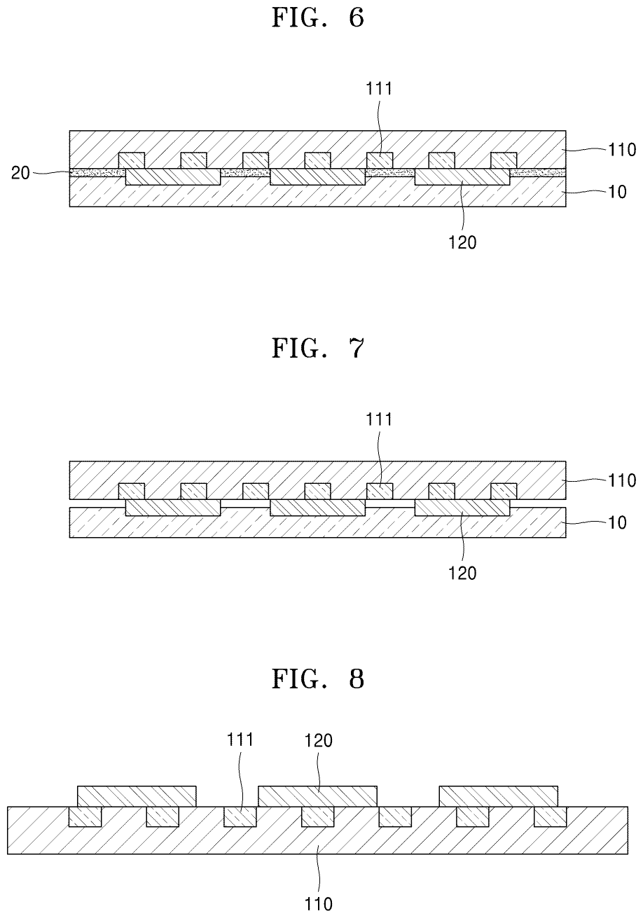

The operation S102 may include an operation of evaporating the liquid in a vacuum. A specific method of bonding a wafer and a chip will be described below with reference to FIGS. 4 to 8.

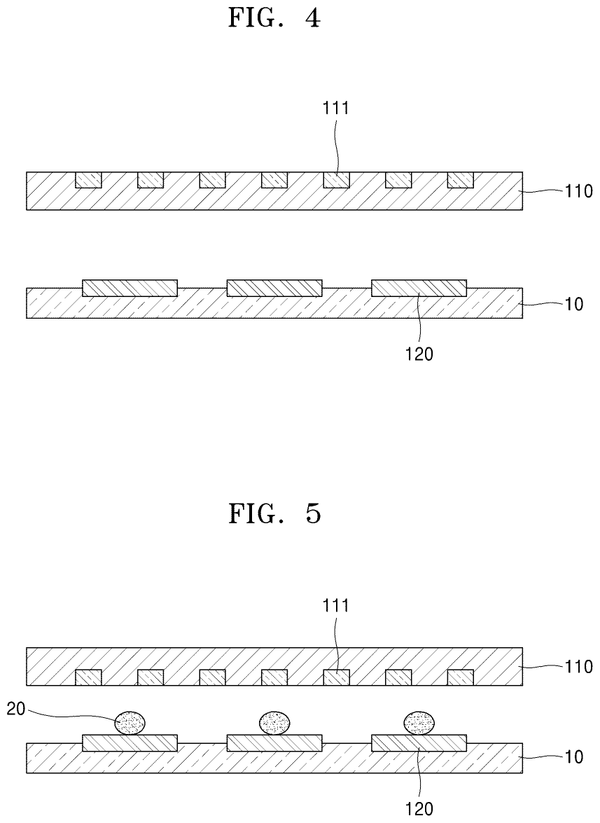

FIG. 3 is a flowchart illustrating a method of bonding a wafer and a chip according to an embodiment.

Referring to FIG. 3, a method of bonding a wafer and a chip may include the operation S101 of preparing a wafer and a chip, the operation S102 of pre-bonding the wafer and the chip using a liquid, the operation S103 of detaching a jig, and an operation S104 of post-bonding the wafer and the chip using heat and pressure.

A specific method of bonding a wafer and a chip will be described below with reference to FIGS. 4 to 8.

FIGS. 4 to 8 are cross-sectional views illustrating a method of bonding a wafer and a chip according to an embodiment. In describing FIGS. 4 to 8, redundant descriptions of FIG. 1 may be omitted.

Referring to FIG. 4, a wafer 110 including at least one device 111 and at least one chip 120 attached to a jig 10 may be provided.

The jig 10 may include a metallic material. The jig 10 may be made by processing a metallic material. The jig 10 may serve to fix the at least one chip 120. The jig 10 may mount the at least one chip 120 or may detach the at least one chip 120 mounted on the jig 10.

A first surface of the jig 10 may have a flat surface, and a second surface of the jig 10, opposite to the first surface, may include a groove in which the chip 120 is attached.

Referring to FIG. 5, a liquid 20 may be dropped on the at least one chip 120 attached to the jig 10, and the wafer 110 including the at least one device 111 may be bonded to the at least one chip 120 attached to the jig 10 by using the liquid 20.

Referring to FIG. 6, the wafer 110 including the at least one device 111 and the at least one chip 120 attached to the jig 10 may be bonded by the surface tension of the liquid 20.

Referring to FIG. 7, the liquid 20 (see FIG. 6) between the wafer 110 including the at least one device 111 and the at least one chip 120 attached to the jig 10 may be removed by applying a vacuum state or by applying heat. For example, at least one pump may be used to apply the vacuum state, and/or at least one heater may be used to apply the heat.

The wafer 110 and the at least one chip 120 may be bonded by removing the liquid 20 (see FIG. 6) from a chamber in a vacuum state from which air is removed. For example, the pump may be configured to remove the air from the chamber such that the chamber is in the vacuum state.

The bonding of the wafer 110 and the at least one chip 120 using the liquid 20 may be referred to as pre-bonding (e.g., operation S102). The pre-bonding may implemented via the surface tension of the liquid 20. Since the surface tension of the liquid 20 is very strong, the wafer 110 and the at least one chip 120 do not separate from each other when pre-bonded, and operability is very excellent.

Referring to FIG. 8, the jig 10 (see FIG. 7) may be detached (e.g., operation S103). After detaching the jig 10 (see FIG. 7), the wafer 110 and the at least one chip 120 may be bonded to each other by performing heating. Alternatively, the wafer 110 and the at least one chip 120 may be bonded to each other by applying heat thereto in a pressurized state.

The bonding of the wafer 110 and the at least one chip 120 using heat and pressure may be referred to as post-bonding (e.g., operation S104). For example, the bonding of the wafer 110 and the at least one chip 120 may be thermocompression bonding.

The post-bonding may be performed under a pressure condition of, for example, 0.5 atm to 4 atm. The post-bonding may be performed under a pressure condition of, for example, 0.5 atm to 10 atm.

The post-bonding may be performed under a temperature condition of, for example, 200° C. to 400° C. The post-bonding may be performed under a temperature condition of, for example, 100° C. to 500° C.

According to some embodiments, at least one bonding device may apply the pressure condition to the wafer 110 and the at least one chip 120, and at least one heater may apply the temperature condition to an environment of the wafer 110 and the at least one chip 120. For example, the at least one bonding device may include at least one body that applies a mechanical force to at least one from among the wafer 110 and the at least one chip 120 such that the pressure condition is applied. During the post-bonding, the wafer 110 and the at least one chip 120 may be in an interior of a chamber, and the interior of the chamber may be the environment, but embodiments of the present disclosure are not limited thereto. According to some embodiments, the chamber in which the post-bonding is performed may be the same or different from the chamber in which the pre-bonding is performed. According to some embodiments, the post-bonding may be performed outside of a chamber.

The post-bonding may change the bonding of the wafer 110 and the at least one chip 120 into a covalent bonding. Specifically, O or OH may exist at the interface of the wafer 110 including silicon, and silicon may be changed into silicon oxide by a chemical reaction. In addition, O or OH may exist at the interface of the at least one chip 120 including the group III-V semiconductor, and the group III-V semiconductor may be combined with the oxide by a chemical reaction. As a result, silicon, O, and III-V materials may be bonded to each other in a connected form.

According to the method of bonding a wafer and at least one chip of some embodiments of the present disclosure, an optical waveguide capable of reducing the surface roughness of an etching surface through oxidation and a method of manufacturing the optical waveguide may be provided. The optical waveguide and the method of manufacturing the optical waveguide have been described with reference to embodiments shown in the drawings.

According to some embodiments of the present disclosure, a method of bonding wafers and chips is provided that utilizes the surface tension of a liquid to bond wafers and chips, resulting in a highly adaptable wafer and chip bonding method.

Example embodiments described herein should be considered in a descriptive sense only and not for purposes of limitation. Descriptions of features or aspects within each embodiment of the present disclosure should typically be considered as available for other similar features or aspects in other embodiments of the present disclosure. While one or more example embodiments have been described with reference to the figures, it will be understood by those of ordinary skill in the art that various changes in form and details may be made therein without departing from the spirit and scope of the present disclosure.

What is claimed is:

1. A method comprising:
pre-bonding, by a liquid, a wafer to a chip, while the chip is attached to a jig; and
detaching the jig after the pre-bonding,
wherein the pre-bonding comprises evaporating the liquid in a vacuum.

2. The method of claim 1, wherein the chip comprises a group III-V semiconductor.

3. The method of claim 1, wherein the liquid comprises oxygen (O).

4. The method of claim 1, wherein the liquid comprises water.

5. The method of claim 1, wherein the wafer comprises a device.

6. The method of claim 5, wherein the device comprises an optical waveguide or an antenna.

7. The method of claim 1, further comprising manufacturing a laser diode by processing the chip.

8. The method of claim 1, wherein the pre-bonding comprises pre-bonding, via a surface tension of the liquid, the wafer to the chip.

9. A method comprising:
pre-bonding, by a liquid, a wafer and a chip, while the chip is attached to a jig;
detaching the jig; and
post-bonding, by heat and pressure, the wafer to the chip after the pre-bonding,
wherein the pre-bonding comprises evaporating the liquid in a vacuum.

10. The method of claim 9, wherein the post-bonding comprises subjecting the wafer and the chip to a pressure in a range of 0.5 atm to 4 atm.

11. The method of claim 9, wherein the post-bonding comprises subjecting the wafer and the chip to a temperature in a range of 200° C. to 400° C.

12. The method of claim 9, wherein the post-bonding comprises changing a bonding of the wafer and the chip, caused by the pre-bonding, into a covalent bonding.

13. The method of claim 9, wherein the chip comprises a group III-V semiconductor.

14. The method of claim 9, wherein the liquid comprises oxygen (O).

15. The method of claim 9, wherein the wafer comprises a device.

16. The method of claim 15, wherein the device comprises an optical waveguide or an antenna.

17. The method of claim 9, further comprising manufacturing a laser diode by processing the chip.

18. The method of claim 9, wherein the pre-bonding comprises pre-bonding, via a surface tension of the liquid, the wafer to the chip.

19. A method comprising:
pre-bonding, by a surface tension of a liquid, a wafer and a chip while the chip is attached to a jig, wherein the chip includes an optical waveguide or an antenna;
detaching the jig; and
post-bonding, by heat and pressure, the wafer to the chip after the pre-bonding,
wherein the pre-bonding comprises evaporating the liquid in a vacuum.

20. The method of claim 19, wherein the post-bonding comprises subjecting the wafer and the chip to a pressure in a range of 0.5 atm to 4 atm and a temperature in a range of 200° C. to 400° C.
